(19) United States
(12) Patent Application Publication
(10) Pub. No.: US 2026/0136953 A1
(43) Pub. Date: May 14, 2026

(54) MULTILAYER INTERPOSER FOR THROUGH GLASS VIA

(71) Applicant: Advanced Micro Devices, Inc., Santa Clara, CA (US)

(72) Inventors: Marzieh Bakhtiary, Austin, TX (US); Sri Ranga Sai Boyapati, Austin, TX (US); Karlos Thomas Leonidas Kazinakis, Austin, TX (US); Kaushik Mysore, Austin, TX (US)

(73) Assignee: Advanced Micro Devices, Inc., Santa Clara, CA (US)

(21) Appl. No.: 18/941,602

(22) Filed: Nov. 8, 2024

(51) Int. Cl. H01L 23/00

(52) U.S. Cl. CPC H10W 70/60; H10W 70/09; H10W 70/6528

(57) ABSTRACT

Techniques are described for interposers comprising through glass vias (TGVs). Some techniques include forming vias in a multilayer interposer that includes a glass layer in addition to layers of an intermediary material arranged above and/or below the glass layer. A conductive path may be formed through the combination of glass layer and intermediary layer or layers that includes a TGV through the glass layer. The intermediary layers may provide a gradual variation in material properties between the glass layer and the layers above and below the multilayer interposer (e.g., dielectric layers).

### BACKGROUND

Interposers are layers used in semiconductor devices to allow multiple components to connect in a single package. In some ways, interposers are similar to bare printed circuit boards (PCBs) in that they provide a substrate for connecting components together and are formed with a large number of through holes (vias). However, interposers provide more flexibility and allow for a higher density of connections than PCBs.

### BRIEF DESCRIPTION OF DRAWINGS

The accompanying drawings illustrate a number of exemplary implementations and are a part of the specification. Together with the following description, these drawings demonstrate and explain various principles of the present disclosure.

FIG. 1A depicts a cross-sectional view of a portion of a device comprising a multilayer interposer, according to some embodiments;

FIG. 1B depicts a cross-sectional view of an illustrative intermediary layer, according to some embodiments;

FIG. 2 depicts a cross-sectional view of a device comprising multiple dies and a multilayer interposer, according to some embodiments;

FIG. 3 is a flowchart of a method of forming a multilayer interposer, according to some embodiments; and

FIGS. 4A-4K depict an illustrative process of forming a multilayer interposer, according to some embodiments.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

As described above, an interposer may provide a number of vias through which components may be galvanically connected. Some interposers are formed from silicon and include conductive vias through the silicon (often called “through silicon vias”), whereas some interposers may be formed from glass and include conductive vias through the glass (often called “through glass vias”). Glass is a desirable material for an interposer, since glass has good mechanical stability, a tailorable coefficient of thermal expansion, and a high electrical resistivity. Furthermore, glass differs from organic materials in that it exhibits low stress and warpage during thermal cycling, providing long-term reliability.

It may be challenging to form vias through a glass interposer in a consistent manner, because voids can form in the conductor when it is deposited into the glass to form the via. Moreover, a via may be formed with a varying diameter, such as an hourglass shape, as a result of the fabrication process, which can lead to mechanical stress under thermal cycling.

Described herein are various examples of interposers for semiconductor devices. For example, techniques are described for forming vias in a multilayer interposer that includes a glass layer in addition to layers of an intermediary material arranged above and/or below the glass layer. A conductive path may be formed through the combination of glass layer and intermediary layer or layers, which includes a through glass via in the glass layer. Since the through glass via may have a smaller thickness than approaches that do not include the intermediary layers, the via may be formed with a more consistent diameter. The intermediary material may have similar properties to glass (e.g., a similar coefficient of thermal expansion and/or Young's modulus). The intermediary layers may provide a gradual variation in material properties between the glass layer and the layers above and below the multilayer interposer, such as dielectric layers.

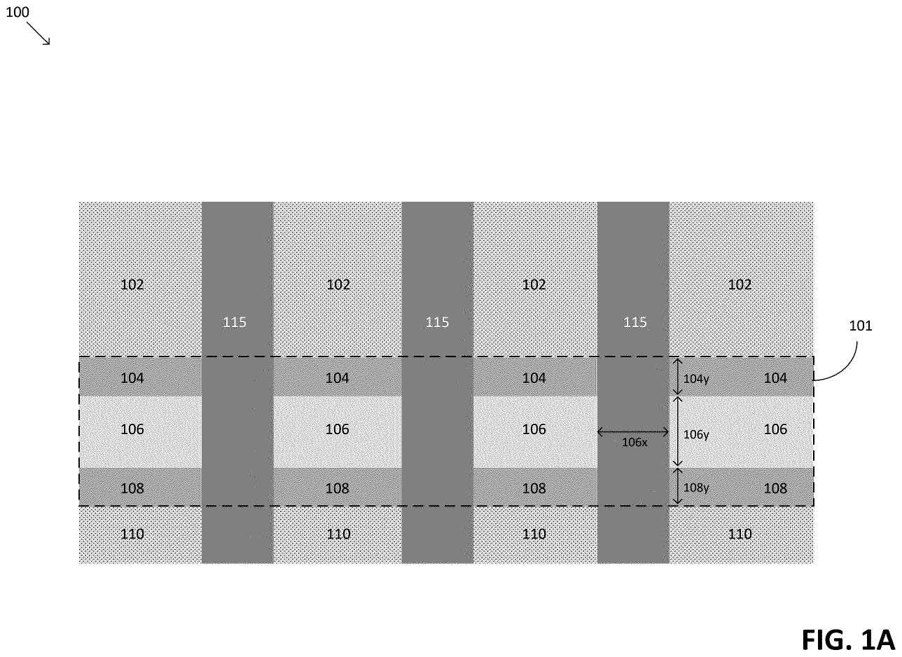

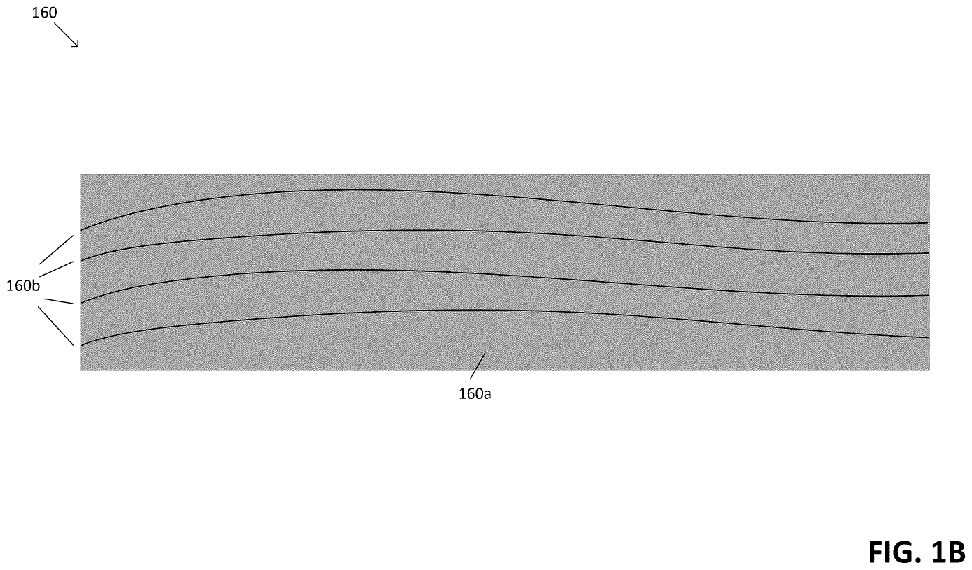

As an illustrative example of the type of device in which the techniques described herein may be practiced, FIG. 1A depicts a cross-sectional view of a portion of a device comprising a multilayer interposer, according to some embodiments. The device of which a portion 100 is shown in FIG. 1A may for instance be a semiconductor organic package. In some embodiments, the portion 100 is part of a semiconductor package that is surface-mounted to a printed circuit board.

In the example of FIG. 1A, the portion 100 of a device includes a multilayer interposer 101, which comprises a glass layer 106 and intermediary layers 104 and 108. Dielectric layers 102 and 110 are arranged above and below the multilayer interposer, respectively. Conductive paths 115 are formed through the dielectric layers and the multilayer interposer.

In the example of FIG. 1A, glass layer 106 comprises, or is formed from, glass (e.g., fused silica, borosilicate glass). In some embodiments, glass layer 106 is doped with one or more materials, including but not limited to boron and/or aluminum. According to some embodiments, glass layer 106 is formed from, or comprises, a boro-aluminosilicate glass (e.g., an alkali-free boro-aluminosilicate glass).

According to some embodiments, a coefficient of thermal expansion (CTE) of the glass layer 106 is greater than or equal to 2 ppm/° K, 3 ppm/° K, 3.5 ppm/° K, 4 ppm/° K, 4.5 ppm/° K, 5 ppm/° K, 6 ppm/° K, or 7 ppm/° K. In some embodiments, the CTE of the glass layer 106 is less than or equal to 10 ppm/° K, 9 ppm/° K, 8 ppm/° K, 7 ppm/° K, 6 ppm/° K, 5 ppm/° K, 4.5 ppm/° K, 4 ppm/° K, 3.5 ppm/° K, or 3 ppm/° K. Any suitable combinations of the above-referenced ranges are also possible (e.g., the CTE of the glass layer 106 is greater or equal to 3 ppm/° K and less than or equal to 10 ppm/° K, or greater than or equal to 3 ppm/° K and less than or equal to 4 ppm/° K, etc.). The CTE of the glass layer 106 as referenced above may be measured at temperatures such as 25° C., 100° C., or 250° C.

According to some embodiments, the glass layer 106 has a Young's Modulus of greater than or equal to 40 GPa, 50 GPa, 60 GPa, 70 GPa, or 80 GPa. In some embodiments, the glass layer 106 has a Young's Modulus of less than or equal to 90 GPa, 80 GPa, 70 GPa, 60 GPa, or 50 GPa. Any suitable combinations of the above-referenced ranges are also possible (e.g., the Young's Modulus of the glass layer 106 is greater or equal to 50 GPa and less than or equal to 80 GPa, or greater or equal to 70 GPa and less than or equal to 80 GPa, etc.).

In the example of FIG. 1A, the intermediary layers 104 and 108 may each be formed from a material having a CTE, Young's modulus, and/or other material properties that lie between those of the glass layer 106 and the dielectric layers 102 and 110, respectively. For example, the intermediary layer 104 may be formed from a material having a CTE that is higher than the CTE of glass layer 106 and lower than the CTE of dielectric layer 102 (so that the CTE lies between that of the glass layer and the dielectric layer). Similarly, the intermediary layer 108 may be formed from a material having a CTE that is higher than the CTE of glass layer 106 and lower than the CTE of dielectric layer 110. As another example, the intermediary layer 104 may be formed from a material having a Young's modulus that is lower than the Young's modulus of glass layer 106 and higher than the Young's modulus of dielectric layer 102; and the intermediary layer 108 may be formed from a material having a Young's modulus that is lower than the Young's modulus of glass layer 106 and higher than the Young's modulus of dielectric layer 110. Such a gradual change in properties may aid in controlling and/or minimizing warpage of portions of a device as its temperature changes, and/or may improve heat dissipation across the layers.

According to some embodiments, the intermediary layer 104 and intermediary layer 108 may each be formed from, or may comprise, an organic polymer containing an embedded material, such as glass (e.g., fused silica). For instance, the intermediary layers 104 and/or 108 may be formed from an organic polymer containing one or more layers of a glass fiber (which may also be referred to as a layer of glass cloth, or a layer of glass weave) embedded in the organic polymer. Organic polymers included in intermediary layers 104 and/or 108 may include epoxies, resins such as phenolic resins, and/or phenolic esters.

FIG. 1B depicts an illustrative example of an intermediary layer 160, which may represent either or both of the intermediary layer 104 and intermediary layer 108, according to some embodiments. In the example of FIG. 1B, the intermediary layer 160 includes an organic polymer 160a (e.g., a phenolic resin or a phenolic ester), and multiple layers of glass fiber 160b embedded within the polymer. The layers of glass fiber 160b may provide an increased mechanical strength over a pure polymer layer, while also providing a lower CTE than a pure polymer layer. In this manner, the intermediary layer 160 may provide a gradual variation in material properties between the glass layer and the layers above and below the multilayer interposer, as described above.

According to some embodiments, a fraction of the intermediary layer 160 that is formed from the organic polymer 160a is greater than or equal to 60 wt %, 65 wt %, 70 wt %, 75 wt % or 80 wt %. In some embodiments, the fraction of the intermediary layer 160 that is formed from the organic polymer 160a is less than or equal to 85 wt %, 80 wt %, 75 wt %, 70 wt %, or 65 wt %. Any suitable combinations of the above-referenced ranges are also possible (e.g., the fraction of the intermediary layer 160 that is formed from the organic polymer 160a is greater or equal to 70 wt % and less than or equal to 80 wt %, etc.). In some embodiments, a remaining fraction of the intermediary layer 160 is provided by the combination of the layers of glass fiber 160b according to any of the above ranges (e.g., the fraction of the intermediary layer 160 that is formed from the layers of glass fiber 160b is greater or equal to 20 wt % and less than or equal to 30 wt %, etc.). In some embodiments, the glass fiber 160b may be provided as a single layer of glass fiber.

According to some embodiments, a thickness of each layer of glass fiber 160b is greater than or equal to 4 μm, 6 μm, 8 μm, 10 μm, 12 μm, 14 μm, or 16 μm. According to some embodiments, the thickness of each layer of glass fiber 160b is greater than or equal to 20 μm, 18 μm, 16 μm, 14 μm, 12 μm, 10 μm, 8 μm, or 6 μm. Any suitable combinations of the above-referenced ranges are also possible (e.g., the thickness of each layer of glass fiber 160b is greater or equal to 8 μm and less than or equal to 12 μm, etc.).

According to some embodiments, the intermediary layer 104 and/or the intermediary layer 108 each has a CTE that is greater than or equal to 2 ppm/° K, 2.5 ppm/° K, 3 ppm/° K, 3.5 ppm/° K, 4 ppm/° K, 4.5 ppm/° K, 5 ppm/° K, or 6 ppm/° K. In some embodiments, the intermediary layer 104 and/or the intermediary layer 108 each has a CTE that is less than or equal to 8 ppm/° K, 7 ppm/° K, 6 ppm/° K, 5 ppm/° K, 4.5 ppm/° K, 4 ppm/° K, 3.5 ppm/° K, or 3 ppm/° K. Any suitable combinations of the above-referenced ranges are also possible (e.g., the intermediary layer 104 and/or the intermediary layer 108 each has a CTE that is greater or equal to 3 ppm/° K and less than or equal to 7 ppm/° K, or greater than or equal to 6 ppm/° K and less than or equal to 8 ppm/° K, etc.). The CTE of the intermediary layer 104 and/or the CTE of the intermediary layer 108 as referenced above may be measured at temperatures such as 25° C., 100° C., or 250° C.

According to some embodiments, the intermediary layer 104 and intermediary layer 108 each has a Young's Modulus of greater than or equal to 10 GPa, 20 GPa, 30 GPa, or 40 GPa. In some embodiments, the intermediary layer 104 and intermediary layer 108 each has a Young's Modulus of less than or equal to 50 GPa, 40 GPa, 30 GPa, or 20 GPa. Any suitable combinations of the above-referenced ranges are also possible (e.g., the intermediary layer 104 and/or intermediary layer 108 has a Young's Modulus that is greater or equal to 20 GPa and less than or equal to 40 GPa, etc.).

In some embodiments, the intermediary layer 104 and/or the intermediary layer 108 contacts the glass layer 106. In some cases, the intermediary layers 104 and/or 108 may have a greater adhesion to the glass layer 106 and to the dielectric layer 102 or 110 than would be expected in a device without intermediary layers, and in which a glass layer is contacting a dielectric layer. As such, the inclusion of the intermediary layers may reduce the possibility of interface failures.

According to some embodiments, the intermediary layer 104 and the intermediary layer 108 each has a thickness (labeled in FIG. 1A as 104y and 108y, respectively) that is greater than or equal to 20 μm, 40 μm, 60 μm, 80 μm, 100 μm, 120 μm, 140 μm, 160 μm, 180 μm, or 200 μm. According to some embodiments, the intermediary layer 104 and the intermediary layer 108 each has a thickness that is less than or equal to 200 μm, 180 μm, 160 μm, 140 μm, 120 μm, 100 μm, 80 μm, 60 μm, or 40 μm. Any suitable combinations of the above-referenced ranges are also possible (e.g., the intermediary layer 104 and/or the intermediary layer 108 has a thickness that is greater or equal to 50 μm and less than or equal to 150 μm, etc.).

According to some embodiments, the glass layer 106 has a thickness (labeled in FIG. 1A as 106y) that is greater than or equal to 100 μm, 150 μm, 200 μm, 250 μm, 300 μm, 400 μm, 500 μm, 600 μm, 700 μm, or 800 μm. According to some embodiments, the glass layer 106 has a thickness that is less than or equal to 800 μm, 700 μm, 600 μm, 500 μm, 450 μm, 400 μm, 350 μm, 300 μm, 250 μm, or 200 μm. Any suitable combinations of the above-referenced ranges are also possible (e.g., the glass layer 106 has a thickness that is greater or equal to 200 μm and less than or equal to 350 μm, etc.).

According to some embodiments, a ratio of a thickness of the glass layer 106 (labeled in FIG. 1A as 106y) to a combined thickness of the intermediary layer 104 and intermediary layer 108 (a sum of the distances labeled in FIG. 1A as 104y and 108y) is greater than or equal to 1, 2, 3, 4, 5 or 6. According to some embodiments, the ratio of the thickness of the glass layer 106 to the combined thickness of the intermediary layer 104 and intermediary layer 108 is less than or equal to 7, 6, 5, 4, 3, or 2. Any suitable combinations of the above-referenced ranges are also possible (e.g., the ratio of the thickness of the glass layer 106 to the combined thickness of the intermediary layer 104 and intermediary layer 108 is greater or equal to 3 and less than or equal to 6, etc.). The relative thicknesses of the glass layer and intermediary layers, as embodied by the aforementioned ratio, may be selected based on an expected warpage (e.g., as predicted by simulation) of the multilayer interposer 101 at various temperatures, which may depend, for example, on the Young's modulus and CTE of the glass layer and the intermediary layers.

According to some embodiments, an aspect ratio of the portion of the conductive path 115 that passes through the glass layer (i.e., 106y divided by 106x as labeled in FIG. 1A, or the inverse) may be greater than or equal to 1, 2, 3, 4, or 5. According to some embodiments, the aspect ratio of the portion of the conductive path 115 that passes through the glass layer may be less than or equal to 7, 6, 5, 4, 3, or 2. Any suitable combinations of the above-referenced ranges are also possible (e.g., the aspect ratio of the portion of the conductive path 115 that passes through the glass layer is greater or equal to 3 and less than or equal to 6, etc.). As the aspect ratio of a through glass via (TGV) increases, it generally becomes more difficult to fill the via with a conductive material during fabrication without producing voids and/or forming the via with a varying diameter. As such, it may be desirable that the aspect ratio of the portion of the conductive path 115 that passes through the glass layer is comparatively lower to improve the consistency of the diameter of the through glass via.

According to some embodiments, the width (106x as labeled in FIG. 1A) of the portion of the conductive path 115 that passes through the glass layer may be substantially consistent along its vertical extent (i.e., from the interface between layers 106 and 108, to the interface between layers 106 and 104). For example, the width of the portion of the conductive path may vary by less than 5%, less than 10%, less than 15% or less than 40% along the aforementioned vertical extent. Variation in this context should be understood to refer to the fractional difference between the greatest width and smallest width in the portion of the conductive path.

According to some embodiments, the conductive paths 115 may be formed from, or may comprise, copper.

According to some embodiments, the dielectric layers 102 and 110 may each be formed from, or may comprise, an electrically insulating material. In some embodiments, the dielectric layers 102 and 110 may each be formed from, or may comprise, an organic polymer. In some embodiments, the dielectric layers 102 and 110 each comprise a build-up layer such as Ajinomoto Build-Up Film (ABF) or Photo Imageable Dielectric (PID).

According to some embodiments, the dielectric layer 102 and dielectric layer 110 each has a CTE that is greater than or equal to 15 ppm/° K, 20 ppm/° K, 25 ppm/° K, or 30 ppm/° K. In some embodiments, the dielectric layer 102 and dielectric layer 110 each has a CTE that is less than or equal to 40 ppm/° K, 35 ppm/° K, 30 ppm/° K, 25 ppm/° K, or 20 ppm/° K. Any suitable combinations of the above-referenced ranges are also possible (e.g., the dielectric layer 102 and/or dielectric layer 110 has a CTE that is greater or equal to 20 ppm/° K and less than or equal to 30 ppm/° K, etc.). The CTE of the dielectric layer 102 and/or dielectric layer 110 as referenced above may be measured at temperatures such as 25° C., 100° C., or 250° C.

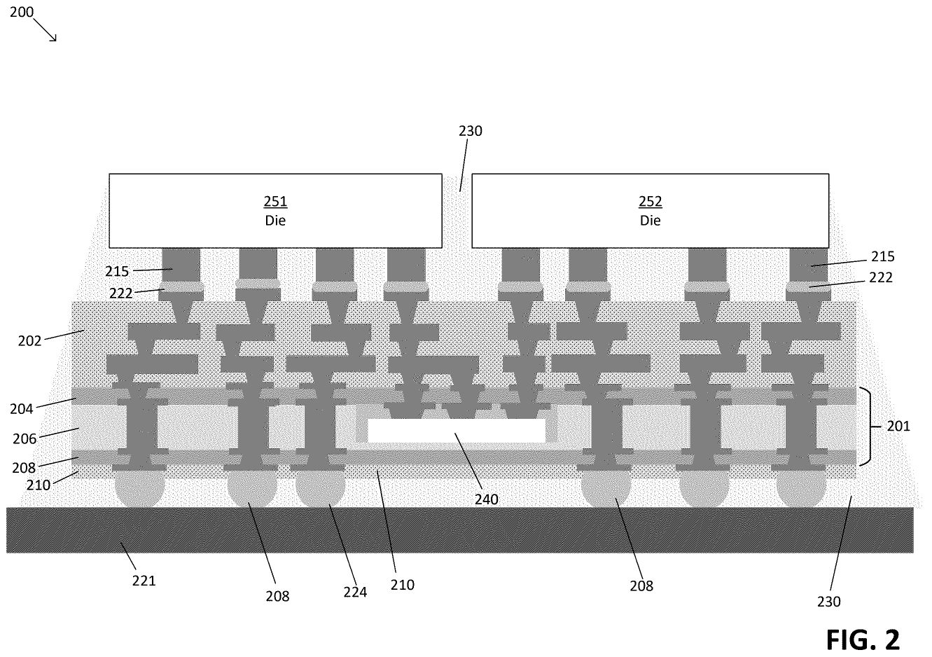

It will be appreciated that FIG. 1A represents a simplified version of a device that may comprise the elements depicted in the drawing. In particular, in practice a conductive path may not be formed as a straight vertical path as shown in FIG. 1A. For instance, typically redistribution layers (RDLs) and other elements are included in a manufactured device that are not shown in the drawing. As such, FIG. 1A is provided merely to describe examples of the various elements shown, and is not intended to accurately represent a manufactured part. However FIG. 2, described below, provides an illustrative example of a device that more closely resembles a manufactured device when compared with FIG. 1A. In addition, while FIG. 1A is depicted with straight electrical routing, it will be appreciated that the device shown in FIG. 1A may also be implemented with fanout routing.

FIG. 2 depicts a cross-sectional view of a device comprising multiple dies and a multilayer interposer, according to some embodiments. In the example of FIG. 2, a package 200 includes dies 251 and 252 which are galvanically connected to a substrate 221 through a multilayer interposer 201 which comprises glass layer 206 and intermediary layers 204 and 208. The package 200 includes dielectric layers 202 and 210 arranged above and below the multilayer interposer 201, respectively. Conductive paths 215, joints 222 and joints 24 couple the dies 251 and 252 to the substrate 221, in addition to interconnect die (ICD) 240, which connects the dies to one another. The joints 224 may in some embodiments be solder balls. A polymer filling 230 is arranged over the aforementioned elements.

FIG. 2 is an example of a device that includes the elements shown in FIG. 1A and described above. As such, multilayer interposer 201, dielectric layer 202, intermediary layer 204, glass layer 206, intermediary layer 208, dielectric layer 210 and conductive paths 215 may be implemented in any of the various ways described above in relation to multilayer interposer 101, dielectric layer 102, intermediary layer 104, glass layer 106, intermediary layer 108, dielectric layer 110 and conductive paths 115, respectively.

According to some embodiments, die 251 and/or die 252 each comprises any suitable semiconductor device, examples of which may include an integrated circuit (e.g., a memory, logic IC, analog IC or processor), a discrete device, an optical device (e.g., light-emitting device, photodetector), a microwave device, or a sensor. According to some embodiments, package 200 may be, or may comprise, a system in package (SiP).

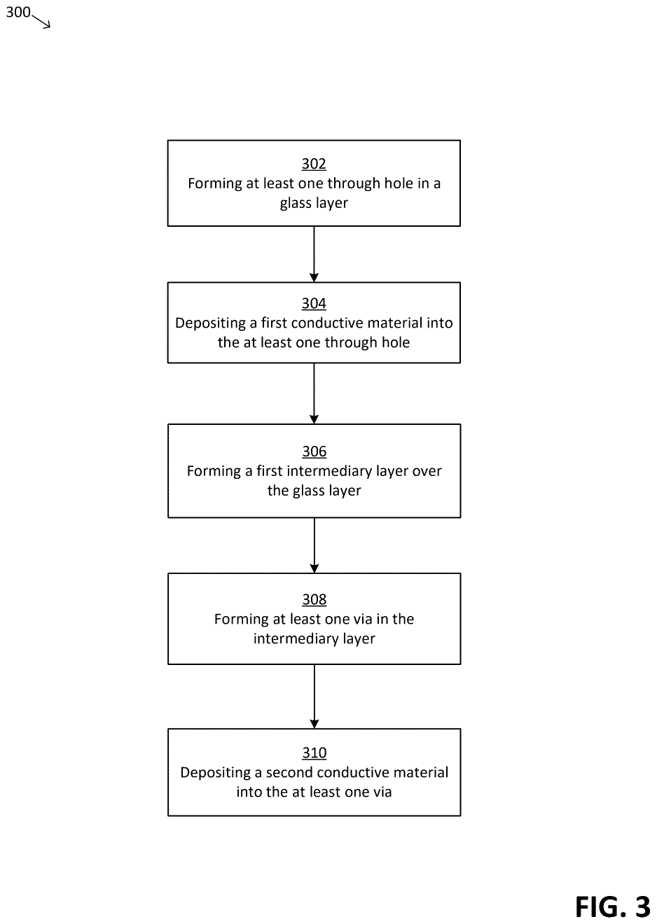

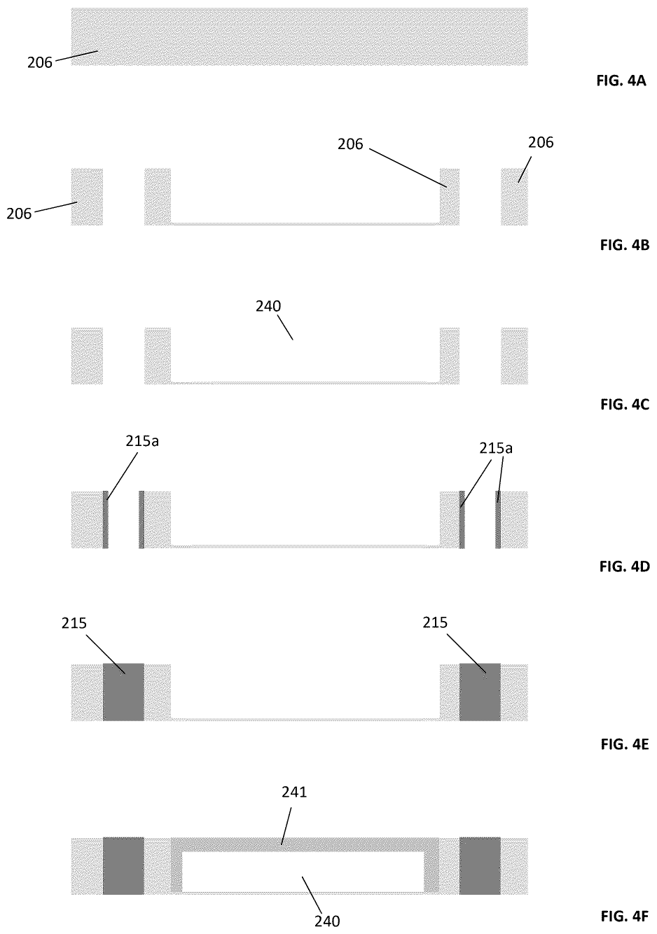

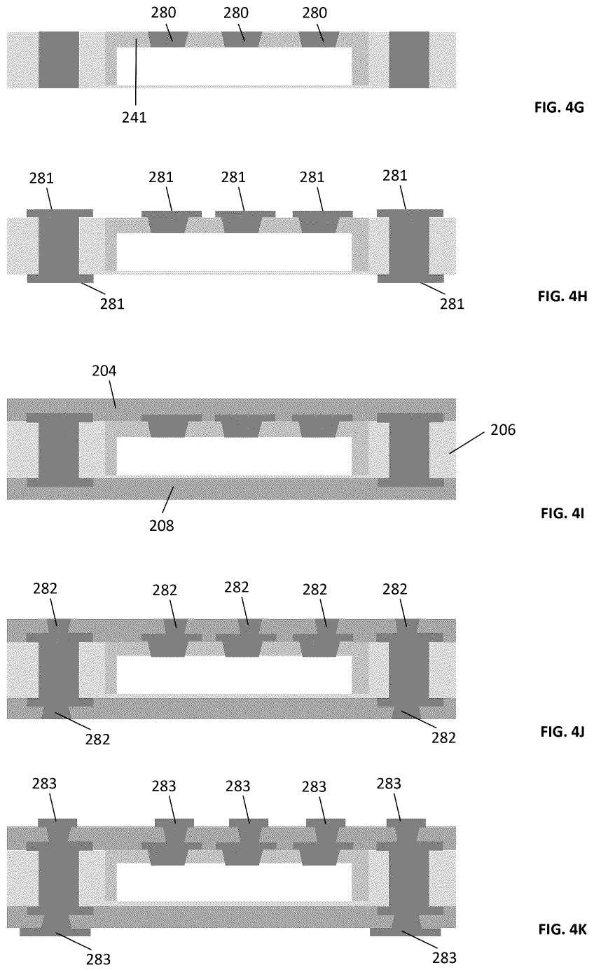

FIG. 3 is a flowchart of a method of forming a multilayer interposer, according to some embodiments. FIGS. 4A-4K depict one illustrative way to implement the acts of this method, according to some embodiments, and are described below in conjunction with the acts of method 300 shown in FIG. 3.

In method 300 and in the example of FIGS. 4A-4K, a portion of package 200 shown in FIG. 2 is formed. It will be appreciated that there may be additional acts performed before, after, or in-between the acts shown in FIG. 3, and/or the acts represented by FIGS. 4A-4K during fabrication, and that FIG. 3 and FIGS. 4A-4K are provided as examples of forming particular parts of this device.

In FIG. 4A, a glass layer 206 is obtained. In accordance with the embodiments described above, the glass layer 206 may for instance comprise, or is formed from, fused silica or borosilicate glass. In some embodiments, glass layer 206 is doped with one or more materials, including but not limited to boron and/or aluminum. According to some embodiments, glass layer 206 is formed from, or comprises, an alkali-free boro-aluminosilicate glass.

The glass layer 206 is then chemically etched to produce a cavity, and in act 302 of method 300 through holes are cut with a laser to produce the structure shown in FIG. 4B. In FIG. 4C, interconnect die 240 is added to the cavity formed in FIG. 4B. In some embodiments, the interconnect die 240 may be arranged on a tape arranged in the cavity.

In FIG. 4D, a seed layer of conductor (e.g., copper) 215a is applied to the interior of the through holes formed in the glass layer 206. For instance, the seed layer of the conductor may be applied via electroless copper seed deposition or physical vapor deposition. These through holes are then filled with conductor in FIG. 4E. A dielectric layer 241 is deposited over the interconnect die 240 as shown in FIG. 4F to produce an upper surface that is flush with the upper surface of the glass layer 206 and the conductive paths 215. Act 304 in method 300 may, for instance, include either or both of the steps of depositing the conductive paths 215a or conductive paths 215 into the through holes as shown in FIGS. 4D and 4E.

In FIG. 4G, vias are created in the dielectric layer 241 (e.g., via photolithography or using a laser) and filled with conductor 280. Pads 281 are then formed with the conductor on top of and on the underside of the glass layer 206 and on top of the dielectric layer 241 in FIG. 4H (e.g., via a semi-additive patterning process or a subtractive patterning process).

In act 306 of method 300, an intermediary layer is formed over the glass layer. In the example of FIG. 4I, an intermediary layer 204 is deposited over the glass layer 206, and an intermediary layer 208 is deposited under the glass layer 206 (e.g., via hot pressing or lamination). In act 308 of method 300 one or more vias are then formed in the intermediary layer formed over the glass layer in act 306. In the example of FIG. 4J, multiple vias are formed in the intermediary layers 204 and 208 (e.g., via photolithography or using a laser).

In act 310 of method 300, a second conductive material (which may be the same type of material as the first conductive material, or a different material) is deposited into the one or more vias formed in act 308. In the example of FIG. 4J, the vias formed in the intermediary layers 204 and 208 are filled with conductor 282 (e.g., via electroless copper seed deposition). In FIG. 4K, pads 283 are then formed with the conductor on top of intermediary layer 204 and on the underside of intermediary layer 208 (e.g., via a semi-additive patterning process or a subtractive patterning process).

Having thus described several aspects of at least one embodiment of this invention, it is to be appreciated that various alterations, modifications, and improvements will readily occur to those skilled in the art. For instance, aspects of the techniques described herein may be combined in any of the following ways:

According to some aspects, the techniques described herein relate to a device including: a glass layer; a first intermediary layer arranged above and in contact with the glass layer; a second intermediary layer arranged below and in contact with the glass layer, wherein the first intermediary layer and the second intermediary layer include an organic polymer containing one or more layers of glass fiber; and a through glass via arranged through the glass layer.

According to some aspects, the techniques described herein relate to a device, further including a conductive path of which the through glass via is a portion, wherein the conductive path passes through the first intermediary layer, the glass layer, and the second intermediary layer.

According to some aspects, the techniques described herein relate to a device, further including: a substrate, wherein the glass layer is arranged over the substrate; a dielectric layer arranged over the first intermediary layer; and a semiconductor die arranged over the dielectric layer, wherein the conductive path galvanically connects the semiconductor die to the substrate, and wherein the conductive path passes through the dielectric layer, the first intermediary layer, the glass layer, and the second intermediary layer.

According to some aspects, the techniques described herein relate to a device, wherein an aspect ratio of the through glass via is between 2 and 5.

According to some aspects, the techniques described herein relate to a device, wherein the glass layer and the first intermediary layer are formed from different materials, and wherein the glass layer and the second intermediary layer are formed from different materials.

According to some aspects, the techniques described herein relate to a device, wherein the glass layer includes boro-aluminosilicate glass.

According to some aspects, the techniques described herein relate to a device, wherein a coefficient of thermal expansion of the first intermediary layer is between 3 ppm/° K and 7 ppm/° K, and wherein a coefficient of thermal expansion of the second intermediary layer is between 3 ppm/° K and 7 ppm/° K.

According to some aspects, the techniques described herein relate to a device, wherein a coefficient of thermal expansion of the glass layer is between 3 ppm/° K and 10 ppm/° K.

According to some aspects, the techniques described herein relate to a device, wherein the dielectric layer includes an organic polymer.

According to some aspects, the techniques described herein relate to a device, wherein the dielectric layer includes a build-up film.

According to some aspects, the techniques described herein relate to a device, wherein a thickness of the glass layer is between 100 μm and 500 μm, and wherein a combined thickness of the first intermediary layer and second intermediary layer is between 50 μm and 250 μm.

According to some aspects, the techniques described herein relate to a device, wherein a ratio between a thickness of the glass layer and a combined thickness of the first intermediary layer and second intermediary layer is between 3 and 15.

According to some aspects, the techniques described herein relate to a device, further including one or more additional conductive paths that galvanically connect the semiconductor die to the substrate and pass through the dielectric layer, the first intermediary layer, the glass layer, and the second intermediary layer.

According to some aspects, the techniques described herein relate to a device, wherein the through glass via is formed from copper.

According to some aspects, the techniques described herein relate to a device, further including a second semiconductor die arranged over the dielectric layer.

According to some aspects, the techniques described herein relate to a device, wherein the glass layer has a Young's modulus of between 50 GPa and 80 GPa, wherein the first intermediary layer has a Young's modulus that is between 20 GPa and 40 GPa, and wherein the second intermediary layer has a Young's modulus that is between 20 GPa and 40 GPa.

According to some aspects, the techniques described herein relate to a method for fabricating a semiconductor package, including: forming at least one through hole in a glass layer; depositing a first conductive material into the at least one through hole in the glass layer; forming a first intermediary layer over and in contact with the glass layer, wherein the first intermediary layer includes an organic polymer containing one or more layers of glass fiber; forming at least one via in the first intermediary layer; and depositing a second conductive material into the at least one via in the first intermediary layer, thereby galvanically connecting the first conductive material and second conductive material.

According to some aspects, the techniques described herein relate to a method, further including: forming a second intermediary layer below and in contact with the glass layer, wherein the second intermediary layer includes the organic polymer containing one or more layers of glass fiber; forming at least one via in the second intermediary layer; and depositing a third conductive material into the at least one via in the second intermediary layer, thereby galvanically connecting the first conductive material, second conductive material and third conductive material.

According to some aspects, the techniques described herein relate to a method, further including, subsequent to depositing the first conductive material into the at least one through hole in the glass layer, forming one or more conductive pads in contact with the first conductive material deposited into the at least one through hole in the glass layer and in contact with an upper surface of the glass layer, and wherein the second conductive material is deposited over the one or more conductive pads.

According to some aspects, the techniques described herein relate to a method, including filling the at least one through hole in the glass layer with the first conductive material.

According to some aspects, the techniques described herein relate to a method, wherein the first conductive material and the second conductive material each includes copper.

According to some aspects, the techniques described herein relate to a device including: a printed circuit board; and a semiconductor package surface-mounted to the printed circuit board, wherein the semiconductor package includes: a substrate; a glass layer arranged over the substrate; a first intermediary layer arranged above and in contact with the glass layer; a second intermediary layer arranged below and in contact with the glass layer, wherein the first intermediary layer and the second intermediary layer include an organic polymer containing one or more layers of glass fiber; a dielectric layer arranged over the first intermediary layer; a semiconductor die arranged over the dielectric layer; and a conductive path that galvanically connects the semiconductor die to the substrate, wherein the conductive path passes through the dielectric layer, the first intermediary layer, the glass layer, and the second intermediary layer.

According to some aspects, the techniques described herein relate to a device, wherein the conductive path includes a through glass via arranged through the glass layer, and wherein the through glass via has an aspect ratio of the through glass via is between 2 and 5.

According to some aspects, the techniques described herein relate to a device, wherein the glass layer and the first intermediary layer are formed from different materials, and wherein the glass layer and the second intermediary layer are formed from different materials.

According to some aspects, the techniques described herein relate to a device, wherein the glass layer includes boro-aluminosilicate glass.

According to some aspects, the techniques described herein relate to a device, wherein a coefficient of thermal expansion of the first intermediary layer is between 3 ppm/° K and 7 ppm/° K, and wherein a coefficient of thermal expansion of the second intermediary layer is between 3 ppm/° K and 7 ppm/° K.

Such alterations, modifications, and improvements are intended to be part of this disclosure, and are intended to be within the spirit and scope of the invention. Further, though advantages of the present invention are indicated, it should be appreciated that not every embodiment of the technology described herein will include every described advantage. Some embodiments may not implement any features described as advantageous herein and in some instances one or more of the described features may be implemented to achieve further embodiments. Accordingly, the foregoing description and drawings are by way of example only.

Various aspects of the present invention may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A device comprising:
a glass layer;
a first intermediary layer arranged above and in contact with the glass layer;
a second intermediary layer arranged below and in contact with the glass layer, wherein the first intermediary layer and the second intermediary layer each comprises an organic polymer containing one or more layers of glass fiber; and
a via arranged through the glass layer.

2. The device of claim 1, further comprising a conductive path of which the via is a portion, wherein the conductive path passes through the first intermediary layer, the glass layer, and the second intermediary layer.

3. The device of claim 2, further comprising:
a substrate, wherein the glass layer is arranged over the substrate;
a dielectric layer arranged over the first intermediary layer; and
a semiconductor die arranged over the dielectric layer,
wherein the conductive path galvanically connects the semiconductor die to the substrate, and
wherein the conductive path passes through the dielectric layer, the first intermediary layer, the glass layer, and the second intermediary layer.

4. The device of claim 1, wherein an aspect ratio of the via is between 2 and 5.

5. The device of claim 1, wherein the glass layer and the first intermediary layer are formed from different materials, and wherein the glass layer and the second intermediary layer are formed from different materials.

6. The device of claim 1, wherein the glass layer comprises boro-aluminosilicate glass.

7. The device of claim 1, wherein a coefficient of thermal expansion of the first intermediary layer is between 3 ppm/° K and 7 ppm/° K, and wherein a coefficient of thermal expansion of the second intermediary layer is between 3 ppm/° K and 7 ppm/° K.

8. The device of claim 1, wherein a thickness of the glass layer is between 100 μm and 500 μm, and wherein a combined thickness of the first intermediary layer and second intermediary layer is between 50 μm and 250 μm.

9. The device of claim 1, wherein a ratio between a thickness of the glass layer and a combined thickness of the first intermediary layer and second intermediary layer is between 3 and 15.

10. The device of claim 1, wherein the glass layer has a Young's modulus of between 50 GPa and 80 GPa, wherein the first intermediary layer has a Young's modulus that is between 20 GPa and 40 GPa, and wherein the second intermediary layer has a Young's modulus that is between 20 GPa and 40 GPa.

11. A method for fabricating a semiconductor package, comprising:
forming at least one through hole in a glass layer;
depositing a first conductive material into the at least one through hole in the glass layer;
forming a first intermediary layer over and in contact with the glass layer, wherein the first intermediary layer comprises an organic polymer containing one or more layers of glass fiber;
forming at least one via in the first intermediary layer; and
depositing a second conductive material into the at least one via in the first intermediary layer, thereby galvanically connecting the first conductive material and second conductive material.

12. The method of claim 11, further comprising:
forming a second intermediary layer below and in contact with the glass layer, wherein the second intermediary layer comprises the organic polymer containing one or more layers of glass fiber;
forming at least one via in the second intermediary layer; and
depositing a third conductive material into the at least one via in the second intermediary layer, thereby galvanically connecting the first conductive material, second conductive material and third conductive material.

13. The method of claim 11, further comprising, subsequent to depositing the first conductive material into the at least one through hole in the glass layer, forming one or more conductive pads in contact with the first conductive material deposited into the at least one through hole in the glass layer and in contact with an upper surface of the glass layer, and wherein the second conductive material is deposited over the one or more conductive pads.

14. The method of claim 11, comprising filling the at least one through hole in the glass layer with the first conductive material.

15. The method of claim 11, wherein the first conductive material and the second conductive material each comprises copper.

16. A device comprising:
a printed circuit board; and
a semiconductor package surface-mounted to the printed circuit board, wherein the semiconductor package comprises:
a substrate;
a glass layer arranged over the substrate;
a first intermediary layer arranged above and in contact with the glass layer;
a second intermediary layer arranged below and in contact with the glass layer, wherein the first intermediary layer and the second intermediary layer each comprises an organic polymer containing one or more layers of glass fiber;
a dielectric layer arranged over the first intermediary layer;
a semiconductor die arranged over the dielectric layer; and
a conductive path that galvanically connects the semiconductor die to the substrate, wherein the conductive path passes through the dielectric layer, the first intermediary layer, the glass layer, and the second intermediary layer.

17. The device of claim 16, wherein the conductive path comprises a via arranged through the glass layer, and wherein the via has an aspect ratio between 2 and 5.

18. The device of claim 16, wherein the glass layer and the first intermediary layer are formed from different materials, and wherein the glass layer and the second intermediary layer are formed from different materials.

19. The device of claim 16, wherein the glass layer comprises boro-aluminosilicate glass.

20. The device of claim 16, wherein a coefficient of thermal expansion of the first intermediary layer is between 3 ppm/° K and 7 ppm/° K, and wherein a coefficient of thermal expansion of the second intermediary layer is between 3 ppm/° K and 7 ppm/° K.
